(19) United States
(12) Patent Application Publication
(10) Pub. No.: US 2025/0168983 A1
(43) Pub. Date: May 22, 2025

(54) CIRCUIT BOARD

(71) Applicant: Mitsubishi Electric Corporation, Tokyo (JP)

(72) Inventor: Takuma AOSHIMA, Tokyo (JP)

(21) Appl. No.: 18/729,016

(22) PCT Filed: Apr. 19, 2022
(86) PCT No.: PCT/JP2022/018210

§ 371 Date: Jul. 15, 2024

(51) Int. Cl. H05K 1/18; H05K 1/11

(52) U.S. Cl. CPC H05K 1/18; H05K 1/11; H05K 2201/1003; H05K 2201/10053; H05K 2201/1006

(57) ABSTRACT

A circuit board includes a plurality of connecting parts that is connectable to components, the plurality of connecting parts includes a first connecting part, a second connecting part, and a third connecting part, and a circuit pattern is formed in which the first connecting part, a power supply circuit, and the third connecting part are connected in series and the second connecting part, the power supply circuit, and the third connecting part are connected in series, and the third connecting part is configured so that two terminals of the third connecting part are short-circuitable when a component that needs power is not connected.

### FIELD

The present disclosure relates to a circuit board including a connecting part for connection with another circuit board.

### BACKGROUND

As an example of a device to which a typical circuit board that includes a connecting part for connection with another circuit board is applied, Patent Literature 1 discloses an air conditioner including a connector for connection of an outdoor unit with an external device. The air conditioner described in Patent Literature 1 is configured so that power is supplied from the external device connected to the connector to the outdoor unit even when a power supply unit included in the outdoor unit is broken, and the external device can read data held by a storage unit included in the outdoor unit.

### CITATION LIST

### Patent Literature

Patent Literature 1: Japanese Patent Application Laid-open No. 2021-18030

### SUMMARY OF INVENTION

### Problem to be Solved by the Invention

Typically, there is a plurality of models having different circuit configurations, even for electric devices for the same use and made by the same manufacturer. For example, for a device that heats water while circulating the water such as floor heating, hot water supply, or radiators, there are many lineups in terms of a heater capacity, a connection method, a tank capacity, the number and positions of pumps, and connection of other actuators. Here, when a circuit board used to control a heater, a pump, and other actuators is individually prepared for each one in the lineup, the number of circuit boards that needs to be designed increases and a development load increases, which results in increase of cost. Therefore, it is desired to realize commonality of the circuit boards in the lineup.

The present disclosure has been made in view of the above, and an object is to realize a circuit board that is applicable to a plurality of different types of devices.

### Means to Solve the Problem

To solve the problems and achieve an object, a circuit board according to the present disclosure includes: a plurality of connecting parts connectable to components, wherein the plurality of connecting parts includes a first connecting part, a second connecting part, and a third connecting part, a circuit pattern is formed in which the first connecting part, a first power supply, and the third connecting part are connected in series, and the second connecting part, the first power supply, and the third connecting part are connected in series, and the third connecting part is configured to enable short-circuit between two terminals of the third connecting part when a component that needs power is not connected.

### Effects of the Invention

A circuit board according to the present disclosure achieves an effect that the circuit board is applicable to a plurality of different types of devices.

### BRIEF DESCRIPTION OF DRAWINGS

FIG. 1 is a diagram illustrating an example of a circuit board and components used in combination with the circuit board according to a first embodiment.

FIG. 2 is a diagram illustrating another example of the circuit board and the components used in combination with the circuit board according to the first embodiment.

FIG. 3 is a diagram illustrating an example of a circuit board and components used in combination with the circuit board according to a second embodiment.

FIG. 4 is a diagram illustrating another example of a connection method of the circuit board and the components used in combination with the circuit board according to the second embodiment.

### DESCRIPTION OF EMBODIMENTS

Hereinafter, a circuit board according to embodiments of the present disclosure will be described in detail with reference to the drawings.

### First Embodiment

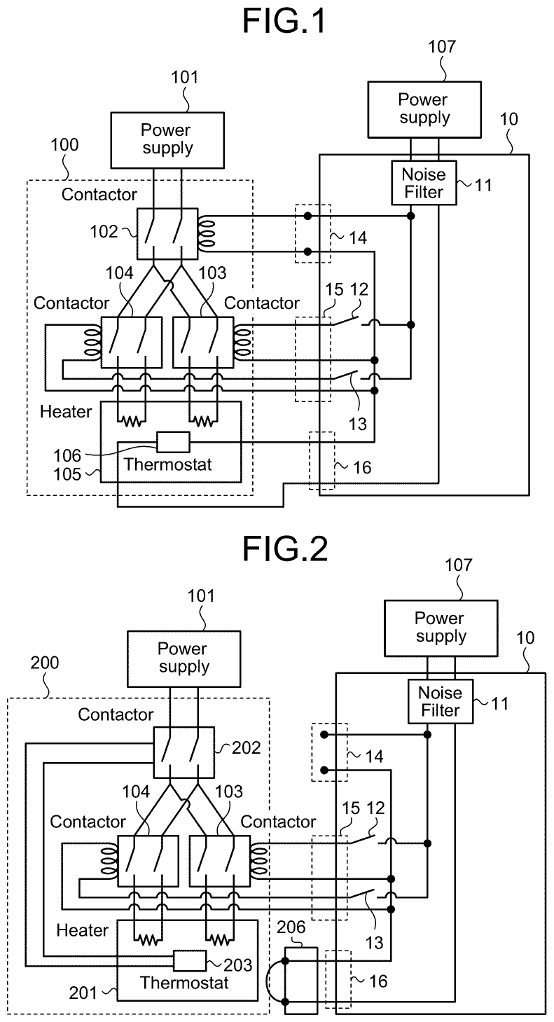

FIG. 1 is a diagram illustrating an example of a circuit board and components used in combination with the circuit board according to a first embodiment. In FIG. 1, an example of a case where a circuit board 10 according to the first embodiment is applied to a device including a heater is illustrated.

The device including the heater includes a protection circuit that prevents an energization state of the heater from continuing when an anomaly or the like occurs. The protection circuit includes a plurality of stages of contactors and thermostats in combination, according to a performance of the heater or the like. Although there are various connection configurations for connecting components included in the protection circuit, it is possible to realize commonality of the circuit board for various devices that use the heater by enabling to share the plurality of connection configurations.

The circuit board 10 illustrated in FIG. 1 is connected to a power supply circuit 107 that is a first power supply. The circuit board 10 includes a noise filter 11 that removes noise components included in power supplied from the power supply circuit 107, and a first connecting part 14, a second connecting part 15, and a third connecting part 16 that are connectable with components. The second connecting part 15 has a configuration in which two components are connected in parallel. Furthermore, relays 12 and 13 are provided between the noise filter 11 and the second connecting part 15. The first connecting part 14, the second connecting part 15, and the third connecting part 16 are composed, for example, of connectors installed on the circuit board 10.

The noise filter 11 includes a common mode choke coil, a Y capacitor, an X capacitor, a surge protection element, or the like. Noise resistance and noise characteristics of emission are improved by passing through the noise filter 11. By installing the noise filter 11 in the circuit board 10, there are advantages such that it is not necessary to individually install the noise filter in each circuit that can be combined with the circuit board 10 and it is possible to prevent extra cost and extra space from being required.

Furthermore, the circuit board 10 is connected to a heater circuit 100 via the first connecting part 14, the second connecting part 15, and the third connecting part 16.

The heater circuit 100 includes contactors 102, 103, and 104 and a heater 105. The heater 105 includes a thermostat 106. When the heater 105 generates abnormal heat, the thermostat 106 detects this and opens between both terminals of the thermostat 106.

The heater circuit 100 is connected to a power supply circuit 101 that is a second power supply. The power supply circuit 101 supplies power to a heating element of the heater 105 via a plurality of multi-connected contactors, specifically, the contactor 102 in a first stage and the contactors 103 and 104 in a second stage. The contactors 102, 103 and 104 form a power supply path from the power supply circuit 101 to the heater 105.

Furthermore, in the heater circuit 100, the contactor 102 is a protection contactor for the heater 105 and forms the protection circuit together with the thermostat 106. The contactors 103 and 104 are control contactors for the heater 105. The heater circuit 100 has a configuration in which the protection contactor and the control contactor are connected in series. Note that, since the number of opening/closing times of the control contactor is large, the plurality of control contactors is generally arranged in parallel so as to prolong an opening/closing life.

Both ends of a coil included in the contactor 102 are connected to the first connecting part 14 of the circuit board 10 and receive supply of power from the power supply circuit 107. Both ends of each of the coils of the contactors 103 and 104 are connected to the second connecting part 15 of the circuit board 10 and receive supply of the power from the power supply circuit 107. Power supply to each of the coils included in the contactors 103 and 104 is controlled by opening/closing the relays 12 and 13 by a control circuit (not illustrated) installed on the circuit board 10. Both ends of the thermostat 106 are connected to the third connecting part 16 of the circuit board 10 and receive supply of the power from the power supply circuit 107.

In a case where the power is supplied from the power supply circuit 107 to the circuit board 10, if the heater 105 of the heater circuit 100 is not anomalously heated, the both ends of the thermostat 106 are short-circuited. Therefore, the contactor 102 is turned on. Moreover, a micro controller or the like controls the relays 12 and 13 so as to energize the coils of the contactors 103 and 104 so that the heater 105 is brought into the energization state. A circuit pattern is formed on the circuit board 10 so that the coil of the contactor 102 connected to the first connecting part 14 and the thermostat 106 connected to the third connecting part 16 have a series relationship and the relays 12 and 13 that respectively control the contactors 103 and 104 connected to the second connecting part 15 and the thermostat 106 connected to the third connecting part 16 have a series relationship. Therefore, when the thermostat 106 detects anomalous heat generation of the heater 105, that is, when a detected temperature by the thermostat 106 is equal to or more than a predetermined threshold, the thermostat 106 is turned off, and the both ends are in an opened state, and as a result, the contactors 102 to 104 are turned off, and it is possible to stop power supply to the heater 105.

FIG. 2 is a diagram illustrating another example of the circuit board and the components used in combination with the circuit board according to the first embodiment. FIG. 2 illustrates an example in a case where the circuit board 10 is applied to a device including a heater, as in FIG. 1. However, a configuration of the components used in combination in FIG. 2 is different from that in FIG. 1.

In the example illustrated in FIG. 2, a heater circuit 200 is connected to the circuit board 10 via the first connecting part 14, the second connecting part 15, and the third connecting part 16. In the heater circuit 200, same reference numerals as those in the heater circuit 100 illustrated in FIG. 1 indicate similar components.

The heater circuit 200 includes the contactors 103 and 104, a capillary thermostat 202, and a heater 201. In the heater 201, a temperature detection unit 203 of the thermostat 202 is provided. The heater circuit 200 has a configuration in which the thermostat 202 is provided between the power supply circuit 101 and the contactors 103 and 104, and when the thermostat 202 detects anomalous heat generation of the heater 201, power supply from the power supply circuit 101 to the contactors 103 and 104 is stopped. Therefore, the first connecting part 14 of the circuit board 10 is in an open state. The open state of the first connecting part 14 is usually realized by the use of a component such as a connector. Furthermore, since the thermostat 202 is not connected to the circuit board 10, a jumper connector 206 poles of which are connected with a lead wire is connected to the third connecting part 16, and two terminals of the third connecting part 16 are short-circuited. Note that the two terminals of the third connecting part 16 may be short-circuited by another method, such as using a jumper line instead of the jumper connector 206.

In the circuit board 10 and the heater circuit 200 illustrated in FIG. 2, when the relays 12 and 13 of the circuit board 10 are closed, a current flows into the coils of the contactors 103 and 104, and the contactors 103 and 104 are turned on. At this time, if the thermostat 202 does not detect anomalous heat generation of the heater 201, power is supplied from the power supply circuit 101 to the heater 201.

As described above, the circuit board 10 according to the present embodiment includes the first connecting part 14, the second connecting part 15, and the third connecting part 16 connected to an external circuit, and can output the power supplied from the power supply circuit 107 to the circuit connected to the first connecting part 14, the second connecting part 15, and the third connecting part 16. Furthermore, the circuit board 10 has a circuit pattern in which the third connecting part 16, the first connecting part 14, and the second connecting part 15 are connected in series. The circuit board 10 can be used in combination with the plurality of types of heater circuits including the protection circuits having the different configurations.

### Second Embodiment

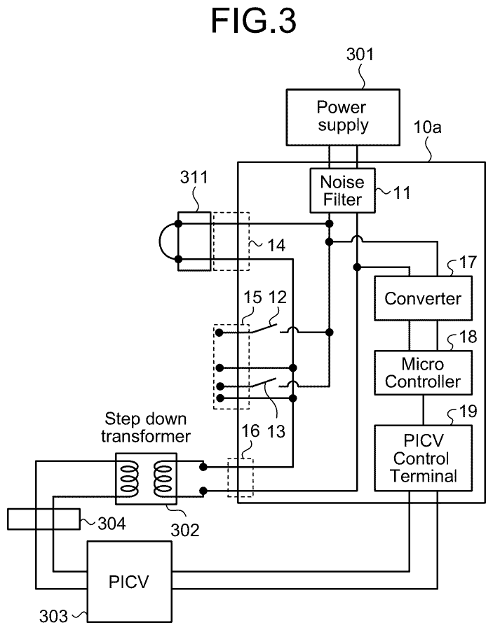

FIG. 3 is a diagram illustrating an example of a circuit board and components used in combination with the circuit board according to a second embodiment. In the first embodiment, the circuit board 10 that can be used in combination with the plurality of heater circuits having the configurations different from each other has been described. However, in the present embodiment, a circuit board that can be used in combination with a device that does not include a heater, that is, a device that does not include the heater circuit such as the heater circuits 100 and 200 described in the first embodiment will be described.

A circuit board 10a according to the second embodiment has a configuration in which a converter 17 that converts AC power into DC power and generates control power, a micro controller 18 that is a control circuit, and a pressure-independent-control-valve-control-terminal 19 are added to the circuit board 10 according to the first embodiment. The converter 17 is implemented by combining a rectifier circuit and an isolated direct current (DC)-DC converter, for example. Similarly to the first connecting part 14 or the like, the pressure-independent-control-valve-control-terminal 19 may include a connector or the like.

To the circuit board 10a, a power supply circuit 301, a transformer 302 that is a step-down transformer, and a pressure independent control valve (PICV) 303 are connected. Specifically, a primary side of the transformer 302 is connected to the third connecting part 16 of the circuit board 10a, and a control signal input terminal of the pressure independent control valve 303 is connected to the pressure-independent-control-valve-control-terminal 19 of the circuit board 10a. Furthermore, a jumper connector 311 is connected to the first connecting part 14 of the circuit board 10a, and two terminals of the first connecting part 14 are short-circuited. Power is supplied from the power supply circuit 301 connected to the circuit board 10a to the transformer 302 via the noise filter 11 and the third connecting part 16. Furthermore, a secondary side of the transformer 302 and a power supply terminal of the pressure independent control valve 303 are connected via a relay connector 304, and power voltage-converted by the transformer 302 is supplied to the pressure independent control valve 303 as driving power. An operation of the pressure independent control valve 303 is controlled by the micro controller 18.

The transformer 302 serves as a down transformer that outputs about 24 V alternating current (AC) when 200 V AC is input from a commercial power supply. By connecting the transformer 302 to a position illustrated in FIG. 3, the transformer 302 is also connected to the noise filter 11 in series, and immunity against burst noise, lightning surge noise, or the like that is coped with in immunity tests is improved as compared with a case where the transformer 302 is directly connected to the commercial power supply. Furthermore, a terminal block, wiring, or the like needed for connection is unnecessary, and power can be directly taken from the circuit board 10a via the third connecting part 16.

The circuit board 10a according to the second embodiment can be used with the device that does not use the heater, in addition to the heater circuits 100 and 200 in the exemplary configurations illustrated in FIGS. 1 and 2 described in the first embodiment. Moreover, in a case of the use method illustrated in FIG. 3, that is, in a case where the circuit board 10a is used with the device that does not use the heater, a cost reduction effect can be obtained by not installing the relays 12 and 13 between the noise filter 11 and the second connecting part 15. When the circuit board 10a is used in combination with the heater circuit 100 or 200 described in the first embodiment, it is sufficient that the micro controller 18 control the relays 12 and 13.

The transformer 302 usually transforms 200 V AC supplied from the commercial power supply into a voltage of about 24 V AC that a person does not get electric shock. However, the transformer 302 also has a role for insulating a primary voltage and a secondary voltage according to safety standards. Usually, the transformer 302 is designed with insulation (basic insulation, reinforced insulation) having an insulation class according to the safety standards. Furthermore, on the circuit board 10a, not only a drive circuit of the connected heater (heater 105 illustrated in FIG. 1 and heater 201 illustrated in FIG. 2) but also the converter 17 that converts an AC voltage into a DC voltage and a control component such as the micro controller 18 are installed. The micro controller 18 transmits a control signal to the pressure independent control valve 303 via the pressure-independent-control-valve-control-terminal 19. Although the transformer 302 performs insulation (basic insulation, reinforced insulation) between the primary side and the secondary side, in a case where the pressure independent control valve 303 is connected to the secondary side, the secondary side of the transformer 302 and the secondary side of the converter 17 are treated in the same way in terms of insulation. By using a converter having a configuration including the isolated DC-DC converter as the converter 17, it is possible to realize a configuration that satisfies immunity and emission as a product while satisfying insulation design of the same device. Furthermore, by using the jumper connector 311 so as to satisfy the connection configuration in FIG. 3 in addition to the connection configurations in FIGS. 1 and 2 described in the first embodiment, the same circuit board 10a can be adopted even in a case where the pattern of connection configurations of the product increases, which is advantageous in terms of development efficiency and development cost.

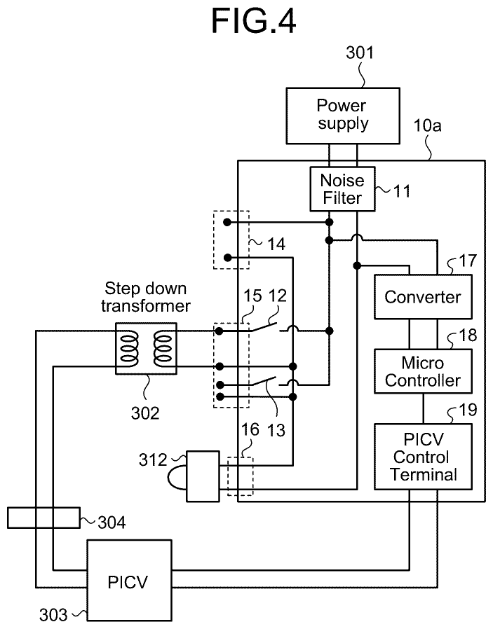

In FIG. 3, an example has been illustrated in which the primary side of the transformer 302 is connected to the third connecting part 16 of the circuit board 10a. However, connection illustrated in FIG. 4 may be used. FIG. 4 is a diagram illustrating another example of a connection method of the circuit board and the components used in combination with the circuit board according to the second embodiment.

In the example illustrated in FIG. 4, the transformer 302 and the pressure independent control valve 303 are connected to the circuit board 10a, as in the example illustrated in FIG. 3. However, a connection position of the transformer 302 is different. Specifically, in the connection method in FIG. 4, the transformer 302 that is connected to the third connecting part 16 in the connection method in FIG. 3 is connected to the second connecting part 15. Furthermore, the jumper connector 312 is connected to the third connecting part 16, and two terminals of the third connecting part 16 are short-circuited.

In the connection method in FIG. 3, since the pressure independent control valve 303 is constantly energized, a standby current always flows. However, it is not necessary to constantly operate the pressure independent control valve 303, and it is sufficient to operate the pressure independent control valve 303 when there is need to adjust a differential pressure generated in an input unit where water enters. Therefore, by using the connection method in FIG. 4, it is possible to supply power to the pressure independent control valve 303 only when there is need to operate. That is, by performing control for closing the relay 12 between the pressure independent control valve 303 and the noise filter 11 when there is need to operate the pressure independent control valve 303 and opening the relay 12 when there is no need to operate the pressure independent control valve 303, it is possible to prevent a current from excessively flowing into a circuit, and it is possible to realize energy saving.

The circuit board 10a according to the present embodiment achieves an effect such that the circuit board 10a can be used in combination with the plurality of types of heater circuits and the circuit board 10a can be used in combination with the pressure independent control valve 303.

The configurations illustrated in the above embodiments indicate examples and can be combined with other known techniques. Furthermore, the embodiments can be combined with each other, and some configurations can be partially omitted or changed without departing from the gist.

### REFERENCE SIGNS LIST

10, 10a circuit board; 11 noise filter; 12, 13 relay; 14 first connecting part; 15 second connecting part; 16 third connecting part; 17 converter; 18 micro controller; 19 pressure independent control valve control terminal; 100, 200 heater circuit; 101, 107, 301 power supply circuit; 102, 103, 104 contactor; 105, 201 heater; 106, 202 thermostat; 203 temperature detection unit; 206, 311, 312 jumper connector; 302 transformer; 303 pressure independent control valve; 304 relay connector.

1. A circuit board comprising:
a plurality of connecting parts connectable to components, wherein
the plurality of connecting parts includes a first connecting part, a second connecting part, and a third connecting part,
a circuit pattern is formed in which the first connecting part, a first power supply, and the third connecting part are connected in series, and the second connecting part, the first power supply, and the third connecting part are connected in series, and
the third connecting part is configured to enable short-circuit between two terminals of the third connecting part when a component that needs power is not connected.

2. The circuit board according to claim 1, wherein
a noise filter is installed between the first connecting part, the second connecting part, and the third connecting part and the first power supply.

3. The circuit board according to claim 1- or 2, wherein
a relay is installed between the first power supply and the second connecting part, and
a protection contactor that is provided on a route where power is supplied from a second power supply to a heater is connected to the first connecting part,
a control contactor of the heater, provided on the route, is connected to the second connecting part, and
a thermostat that opens a circuit when detecting a state where a temperature near the heater is equal to or more than a predetermined threshold, is connected to the third connecting part.

4. The circuit board according to claim 1- or 2, wherein
a relay is installed between the first power supply and the second connecting part, and
a control contactor for a heater, provided on a route where power is supplied from a second power supply to the heater, is connected to the second connecting part, and
a jumper connector that short-circuits between two terminals of the third connecting part is connected to the third connecting part.

5. The circuit board according to claim 1- or 2, comprising:
a converter to convert power to be supplied from the first power supply into control power; a control circuit to operate upon receiving supply of the control power; and a pressure-independent-control-valve-control-terminal to output a control signal for a pressure independent control valve generated by the control circuit, wherein
a transformer that generates driving power of the pressure independent control valve is connected to the third connecting part, a jumper connector that short-circuits between two terminals of the first connecting part is connected to the first connecting part, and a control signal input terminal of the pressure independent control valve is connected to the pressure-independent-control-valve-control-terminal.

6. The circuit board according to claim 1- or 2, wherein
a relay is installed between the first power supply and the second connecting part,
the circuit board comprises:
a converter to convert power to be supplied from the first power supply into control power; a control circuit to operate upon receiving supply of the control power; and a pressure-independent-control-valve-control-terminal to output a control signal of a pressure independent control valve generated by the control circuit, and
a transformer that generates driving power of the pressure independent control valve is connected to the second connecting part, a jumper connector that short-circuits between two terminals of the third connecting part is connected to the third connecting part, and a control signal input terminal of the pressure independent control valve is connected to the pressure-independent-control-valve-control-terminal.

7. The circuit board according to claim 2, wherein
a relay is installed between the first power supply and the second connecting part, and
a protection contactor that is provided on a route where power is supplied from a second power supply to a heater is connected to the first connecting part,
a control contactor of the heater, provided on the route, is connected to the second connecting part, and
a thermostat that opens a circuit when detecting a state where a temperature near the heater is equal to or more than a predetermined threshold, is connected to the third connecting part.

8. The circuit board according to claim 2, wherein
a relay is installed between the first power supply and the second connecting part, and
a control contactor for a heater, provided on a route where power is supplied from a second power supply to the heater, is connected to the second connecting part, and
a jumper connector that short-circuits between two terminals of the third connecting part is connected to the third connecting part.

9. The circuit board according to claim 2, comprising:
a converter to convert power to be supplied from the first power supply into control power; a control circuit to operate upon receiving supply of the control power; and a pressure-independent-control-valve-control-terminal to output a control signal for a pressure independent control valve generated by the control circuit, wherein
a transformer that generates driving power of the pressure independent control valve is connected to the third connecting part, a jumper connector that short-circuits between two terminals of the first connecting part is connected to the first connecting part, and a control signal input terminal of the pressure independent control valve is connected to the pressure-independent-control-valve-control-terminal.

10. The circuit board according to claim 2, wherein
a relay is installed between the first power supply and the second connecting part,
the circuit board comprises:
a converter to convert power to be supplied from the first power supply into control power; a control circuit to operate upon receiving supply of the control power; and a pressure-independent-control-valve-control-terminal to output a control signal of a pressure independent control valve generated by the control circuit, and
a transformer that generates driving power of the pressure independent control valve is connected to the second connecting part, a jumper connector that short-circuits between two terminals of the third connecting part is connected to the third connecting part, and a control signal input terminal of the pressure independent control valve is connected to the pressure-independent-control-valve-control-terminal.
